(19) United States
(12) Patent Application Publication
(10) Pub. No.: US 2013/0316538 A1
(43) Pub. Date: Nov. 28, 2013

(54) SURFACE MORPHOLOGY GENERATION AND TRANSFER BY SPALLING

(71) Applicants: Stephen W. Bedell, Wappingers Falls, NY (US); Keith E. Fogel, Hopewell Junction, NY (US); Augustin J. Hong, White Plains, NY (US); Ning Li, White Plains, NY (US); Devendra K. Sadana, Pleasantville, NY (US); Katherine L. Saenger, Ossining, NY (US); Davood Shahrjerdi, White Plains, NY (US); Kuen-Ting Shiu, White Plains, NY (US)

(72) Inventors: Stephen W. Bedell, Wappingers Falls, NY (US); Keith E. Fogel, Hopewell Junction, NY (US); Augustin J. Hong, White Plains, NY (US); Ning Li, White Plains, NY (US); Devendra K. Sadana, Pleasantville, NY (US); Katherine L. Saenger, Ossining, NY (US); Davood Shahrjerdi, White Plains, NY (US); Kuen-Ting Shiu, White Plains, NY (US)

(73) Assignee: INTERNATIONAL BUSINESS MACHINES CORPORATION, Armonk, NY (US)

(21) Appl. No.: 13/478,749

(22) Filed: May 23, 2012

(51) Int. Cl. H01L 21/304; H01L 21/306

(52) U.S. Cl. 438/691; 438/759; 257/E21.237; 257/E21.215

(57) ABSTRACT

The generation of surface patterns or the replication of surface patterns is achieved in the present disclosure without the need to employ an etching process. Instead, a unique fracture mode referred to as spalling is used in the present disclosure to generate or replicate surface patterns. In the case of surface pattern generation, a surface pattern is provided in a stressor layer and then spalling is performed. In the case of surface pattern replication, a surface pattern is formed within or on a surface of a base substrate, and then a stressor layer is applied. After applying the stressor layer, spalling is performed. Generation or replication of surface patterns utilizing spalling provides a low cost means for generation or replication of surface patterns.

### BACKGROUND

The present disclosure relates to semiconductor manufacturing, and more particularly to methods for generating or replicating (i.e., transferring) surface patterns utilizing spalling. Pattern generation processes on semiconductor surfaces typically involve a mask patterning process, followed by wet or dry etch processes. In the field of photovoltaic devices, i.e., solar cells, the use of prior art pattern generation processes increases the cost of fabricating photovoltaic devices. Processes that can reduce the cost of manufacturing photovoltaic devices by simplifying or eliminating prior art pattern generation processes are greatly desirable. Also, there is a need for providing a method in which surface patterns can be replicated, i.e., transferred, from one structure to other structures without the need of using prior art pattern generation processes.

### SUMMARY

The generation of surface patterns or the replication of surface patterns is achieved in the present disclosure without the need to employ an etching process. Instead, a unique fracture mode referred to as spalling is used in the present disclosure to generate or replicate surface patterns. The term “spalling” is used throughout the present disclosure to denote a process in which a stressor layer having carefully tuned properties (i.e., stress level and stressor layer thickness) is formed atop a base substrate whereby the stressor layer can generate fracture surfaces within the base substrate in which crack initiation and propagation occurs.

The term “surface pattern” denotes a selected surface morphology of a structure including, for example, a selected surface morphology of a stressor layer, a selected surface morphology of a base substrate, or a selected surface morphology of a mask formed atop a base substrate. The selected surface morphology of a stressor layer can be achieved by providing a stressor layer having a modulation, i.e., non-uniformity, in thickness or in a physical property. That is, one region of the stressor layer has a different thickness or physical property as compared to at least one other region of the stressor layer. Such a stressor layer is referred to herein as a “differential-fracture-generating-stressor layer.”

In the case of surface pattern generation, a surface pattern is provided to a stressor layer and then spalling is performed. In the case of surface pattern replication, a surface pattern is formed within, or on, a surface of a base substrate, and then a stressor layer is applied. After applying the stressor layer, spalling is performed.

In one aspect of the present disclosure, a method of generating surface patterns is provided that does not include an etching of a base substrate. This aspect of the present disclosure includes forming a differential-fracture-generating-stressor layer atop a base substrate. The differential-fracture-generating-stressor layer has a modulation in thickness or at least one physical property. A material layer is then spalled from the base substrate. After spalling, the material layer from the base substrate and a remaining portion of the base substrate have complementary surface morphologies that follow the modulation in thickness or the physical property of the differential-fracture-generating-stressor layer.

In another aspect of the present disclosure, a method of replicating surface patterns is provided. This aspect of the present disclosure includes providing a base substrate having a selected surface morphology. A stressor layer is formed atop the base substrate and its selected surface morphology. A material layer is then spalled from the base substrate. After spalling, the material layer from the base substrate has a spalled surface that at least partially replicates the selected surface morphology, and a remaining portion of the base substrate has a surface with a morphology complementary to the at least partially replicated surface morphology.

Generation or replication of surface patterns utilizing spalling as described in the present disclosure provides a low cost means for generation or replication of surface patterns. The generation or the replication of surface patterns utilizing spalling as described in the present disclosure can be used in a wide variety of applications including, for example, in photovoltaic device, i.e., solar cell, manufacturing, and flexible stretchable electronic fabrication.

### BRIEF DESCRIPTION OF THE DRAWINGS

FIG. 1 is a pictorial representation (through a cross sectional view) illustrating a base substrate that can be employed in one embodiment of the present disclosure.

FIG. 2 is a pictorial representation (through a cross sectional view) illustrating the base substrate of FIG. 1 after forming an optional metal-containing adhesion layer on a surface of the base substrate.

FIG. 3A is a pictorial representation (through a cross sectional view) illustrating the structure of FIG. 2 after forming a differential-fracture-generating-stressor layer having a non-uniformity in thickness on a surface of the optional metal-containing adhesion layer.

FIG. 3B is a pictorial representation (through a cross sectional view) illustrating the structure of FIG. 2 after forming a differential-fracture-generating-stressor layer having a non-uniformity in at least one physical property on a surface of the optional metal-containing adhesion layer.

FIG. 4A is a pictorial representation (through a cross sectional view) illustrating the structure of FIG. 3A after forming an optional handle substrate atop the differential-fracture-generating-stressor layer.

FIG. 4B is a pictorial representation (through a cross sectional view) illustrating the structure of FIG. 3B after forming an optional handle substrate atop the differential-fracture-generating-stressor layer.

FIG. 5A is a pictorial representation (through a cross sectional view) illustrating the structure of FIG. 4A after spalling.

FIG. 5B is a pictorial representation (through a cross sectional view) illustrating the structure of FIG. 4B after spalling.

FIG. 6A is a pictorial representation (through a cross sectional view) illustrating a structure after forming a differential-fracture-generating-stressor layer having a non-uniformity in thickness atop a base substrate, the non-uniformity of the differential-fracture-generating-stressor layer is located near one edge of the base substrate.

FIG. 6B is a pictorial representation (through a cross sectional view) illustrating a structure after forming a differential-fracture-generating-stressor layer having a non-uniformity in at least one physical property located atop a base substrate, the non-uniformity of the differential-fracture-generating-stressor layer is located near one edge of the base substrate.

FIG. 7A is a pictorial representation (through a cross sectional view) illustrating the structure of FIG. 6A after spalling.

FIG. 7B is a pictorial representation (through a cross sectional view) illustrating the structure of FIG. 6B after spalling.

FIG. 8 is a pictorial representation (through a cross sectional view) illustrating a base substrate having a non-uniform uppermost surface that can be employed in another embodiment of the present disclosure.

FIG. 9 is a pictorial representation (through a cross sectional view) illustrating the base substrate of FIG. 8 after forming an optional metal-containing adhesion layer on the uppermost surface of the base substrate.

FIG. 10 is a pictorial representation (through a cross sectional view) illustrating the structure of FIG. 9 after forming a stressor layer on a surface of the optional metal-containing adhesion layer.

FIG. 11 is a pictorial representation (through a cross sectional view) illustrating the structure of FIG. 10 after forming an optional handle substrate atop the stressor layer.

FIG. 12 is a pictorial representation (through a cross sectional view) illustrating the structure of FIG. 11 after spalling.

FIG. 13 is a pictorial representation (through a cross sectional view) illustrating the base substrate of FIG. 1 after forming a mask having at least one opening atop the base substrate.

FIG. 14 is a pictorial representation (through a cross sectional view) illustrating the structure of FIG. 13 after forming a stressor layer atop the mask.

FIG. 15 is a pictorial representation (through a cross sectional view) illustrating the structure of FIG. 14 after spalling.

FIG. 16 is a pictorial representation (through a cross sectional view) illustrating a base substrate having a non-uniform uppermost surface that can be employed in another embodiment of the present disclosure.

FIG. 17 is a pictorial representation (through a cross sectional view) illustrating the structure of FIG. 16 after forming a stressor layer atop the base substrate.

FIG. 18 is a pictorial representation (through a cross sectional view) illustrating the structure of FIG. 17 after spalling.

### DETAILED DESCRIPTION

The present disclosure, which discloses methods for generating or replicating surface patterns utilizing spalling, will now be described in greater detail by referring to the following discussion and drawings that accompany the present application. It is noted that the drawings of the present application are provided for illustrative purposes and, as such, they are not drawn to scale. In the drawings and the description that follows, like elements are referred to by like reference numerals. For purposes of the description hereinafter, the terms “upper”, “lower”, “right”, “left”, “vertical”, “horizontal”, “top”, “bottom”, and derivatives thereof shall relate to the components, layers and/or elements as oriented in the drawing figures which accompany the present application.

In the following description, numerous specific details are set forth, such as particular structures, components, materials, dimensions, processing steps and techniques, in order to provide a thorough understanding of the present disclosure. However, it will be appreciated by one of ordinary skill in the art that the present disclosure may be practiced with viable alternative process options without these specific details. In other instances, well-known structures or processing steps have not been described in detail in order to avoid obscuring the various embodiments of the present disclosure.

As stated above, the present disclosure provides methods in which spalling is employed to generate or replicate surface patterns. The generation and replication of surface patterns is achieved in the present disclosure without the need to employ an etching process. In one embodiment of the present disclosure, surface pattern generation and replication can be applied to “surface texturing.” In such an embodiment, the absorption of sunlight is enhanced by texturing the surface of a semiconductor material to trap light via multiple reflections. Such texturing is especially useful in single crystalline solar cell manufacturing. High quality surface texturing comprising inverted pyramids is usually made by photolithography followed by anisotropic etching. Surface texturing increases the efficiency of the solar cells, but also increases the cost of the solar cell due to the addition of several processing steps. Using the spalling methods of the present disclosure for surface pattern generation and replication can reduce the cost of surface texturing. Furthermore, processes that use anisotropic etching for surface texturing have limited applicability. Typically, prior art processes that use anisotropic etching for surface texturing are applicable to Si (100) and Ge (100) single crystals. The spalling methods of the present disclosure can easily be applied to all materials and all orientations which can greatly broaden the applications of light trapping and surface texturing.

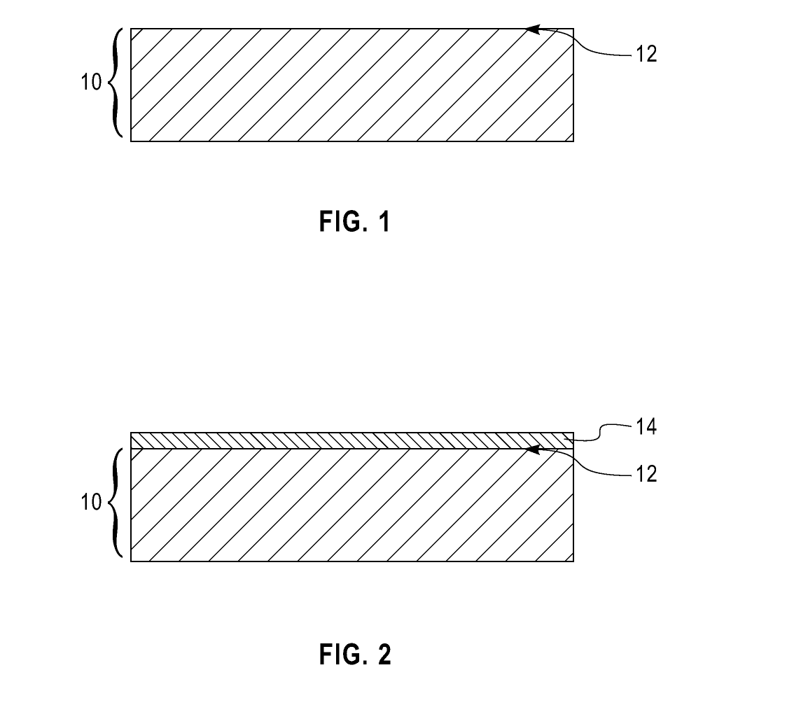

In one aspect of the present disclosure, spalling is used to generate surface patterns. This aspect of the present disclosure will now be described in greater detail by referring to FIGS. 1-7B. In this aspect of the present disclosure, a differential-fracture-generating-stressor layer having a modulation in thickness or at least one physical property is formed atop a base substrate. Next, a material layer from the base substrate is spalled. In accordance with this aspect of the present disclosure, the material layer from the base substrate and a remaining portion of the base substrate have complementary surface morphologies that follow the modulation in thickness or the at least one physical property of the differential-fracture-generating-stressor layer.

Referring first to FIG. 1, there is illustrated a base substrate 10 having an uppermost surface 12 that can be employed in one embodiment of the present disclosure. The base substrate 10 that can be employed in one embodiment of the present disclosure may comprise a semiconductor material, a glass, a ceramic, or any another material whose fracture toughness is less than that of the stressor material to be subsequently described. In this particular embodiment, the uppermost surface 12 of the base substrate 10 is entirely planar.

Fracture toughness is a property which describes the ability of a material containing a crack to resist fracture. Fracture toughness is denoted K_{Ic}. The subscript Ic denotes mode I crack opening under a normal tensile stress perpendicular to the crack, and c signifies that it is a critical value. Mode I fracture toughness is typically the most important value because spalling mode fracture usually occurs at a location in the substrate where mode II stress (shearing) is zero, and mode III stress (tearing) is generally absent from the loading conditions. Fracture toughness is a quantitative way of expressing a material's resistance to brittle fracture when a crack is present.

When the base substrate 10 comprises a semiconductor material, the semiconductor material may include, but is not limited to, Si, Ge, SiGe, SiGeC, SiC, Ge alloys, GaSb, GaP, GaAs, InAs, InP, and all other III-V or II-VI compound semiconductors. In some embodiments, the base substrate 10 is a bulk semiconductor material. In other embodiments, the base substrate 10 may comprise a layered semiconductor material such as, for example, a semiconductor-on-insulator or a semiconductor on a polymeric substrate. Illustrated examples of semiconductor-on-insulator substrates that can be employed as base substrate 10 include silicon-on-insulators and silicon-germanium-on-insulators.

When the base substrate 10 comprises a semiconductor material, the semiconductor material can be doped, undoped or contain doped regions and undoped regions.

In one embodiment, the semiconductor material that can be employed as the base substrate 10 can be single crystalline (i.e., a material in which the crystal lattice of the entire sample is continuous and unbroken to the edges of the sample, with no grain boundaries). In another embodiment, the semiconductor material that can be employed as the base substrate 10 can be polycrystalline (i.e., a material that is composed of many crystallites of varying size and orientation; the variation in direction can be random (called random texture) or directed, possibly due to growth and processing conditions). In some embodiments, and when the semiconductor material is a polycrystalline material, the material of the present disclosure spalls certain grains, while leaving certain grains unspalled. As such, spalling of polycrystalline semiconductor material using the method of the present disclosure may produce a non-continuous spalled material layer. In yet another embodiment of the present disclosure, the semiconductor material that can be employed as the base substrate 10 can be amorphous (i.e., a non-crystalline material that lacks the long-range order characteristic of a crystal). Typically, the semiconductor material that can be employed as the base substrate 10 is a single crystalline material.

When the base substrate 10 comprises a glass, the glass can be an SiO₂-based glass which may be undoped or doped with an appropriate dopant. Examples of SiO₂-based glasses that can be employed as the base substrate 10 include undoped silicate glass, borosilicate glass, phosphosilicate glass, fluorosilicate glass, and borophosphosilicate glass.

When the base substrate 10 comprises a ceramic, the ceramic is any inorganic, non-metallic solid such as, for example, an oxide including, but not limited to, alumina, beryllia, ceria and zirconia, a non-oxide including, but not limited to, a carbide, a boride, a nitride or a silicide; or composites that include combinations of oxides and non-oxides.

In some embodiments of the present disclosure, one or more devices including, but not limited to, transistors, capacitors, diodes, BiCMOS, resistors, etc. can be processed on and/or within the uppermost surface 12 of the base substrate 10 utilizing techniques well known to those skilled in the art. The upper portion of the base substrate that includes the one or more devices can be removed utilizing the methods of the present disclosure.

In some embodiments of the present disclosure, the uppermost surface 12 of the base substrate 10 can be cleaned prior to further processing to remove surface oxides and/or other contaminants therefrom. In one embodiment of the present disclosure, the base substrate 10 is cleaned by applying to the base substrate 10 a solvent such as, for example, acetone and isopropanol, which is capable of removing contaminates and/or surface oxides from the uppermost surface 12 of the base substrate 10.

In some embodiments of the present disclosure, the uppermost surface 12 of the base substrate 10 can be made hydrophobic by oxide removal prior to use by dipping the uppermost surface 12 of the base substrate 10 into hydrofluoric acid. A hydrophobic, or non-oxide, surface provides improved adhesion between the cleaned surface and certain stressor materials to be deposited.

Referring now to FIG. 2, there is illustrated the base substrate 10 of FIG. 1 after forming an optional metal-containing adhesion layer 14 on the uppermost surface 12 of base substrate 10. The optional metal-containing adhesion layer 14 is employed in embodiments in which the stressor material to be subsequently formed has poor adhesion to uppermost surface 12 of base substrate 10. Typically, the metal-containing adhesion layer 14 is employed when a stressor material comprised of a metal is employed. In some embodiments, an optional plating seed layer (not shown) can be formed directly atop the uppermost surface 12 of the base substrate 10. In other embodiments, both optional layers, i.e., a metal-containing adhesion layer and a plating seed layer, can be used.

The optional metal-containing adhesion layer 14 that may employed in the present disclosure includes any metal adhesion material such as, but not limited to, Ti/W, Ti, Cr, Ni or any combination thereof. The optional metal-containing adhesion layer 14 may comprise a single layer or it may include a multilayered structure comprising at least two layers of different metal adhesion materials.

The metal-containing adhesion layer 14 that can be optionally formed on the uppermost surface 12 of base substrate 10 is formed at room temperature (15° C.-40° C., i.e., 288K to 313K) or above. In one embodiment, the optional metal-containing adhesion layer 14 is formed at a temperature which is from 20° C. (293K) to 180° C. (353K). In another embodiment, the optional metal-containing adhesion layer 14 is formed at a temperature which is from 20° C. (293K) to 60° C. (333K).

The metal-containing adhesion layer 14, which may be optionally employed, can be formed utilizing deposition techniques that are well known to those skilled in the art. For example, the optional metal-containing adhesion layer 14 can be formed by sputtering, chemical vapor deposition, plasma enhanced chemical vapor deposition, chemical solution deposition, physical vapor deposition, and plating. When sputter deposition is employed, the sputter deposition process may further include an in-situ sputter clean process before the deposition.

When employed, the optional metal-containing adhesion layer 14 typically has a thickness from 5 nm to 200 nm, with a thickness from 100 nm to 150 nm being more typical. Other thicknesses for the optional metal-containing adhesion layer 14 that are below and/or above the aforementioned thickness ranges can also be employed in the present disclosure.

The optional plating seed layer (not shown) is typically employed in embodiments in which the stressor material to be subsequently formed is a metal and plating is used to form the metal-containing stressor material. The optional plating seed layer is employed to selectively promote subsequent plating of a pre-selected metal-containing stressor material. The optional plating seed layer may comprise, for example, a single layer of Ni or a layered structure of two or more metals such as Al(bottom)/Ti/Ni(top).

The thickness of the optional plating seed layer may vary depending on the material or materials of the optional plating seed layer as well as the technique used in forming the same. Typically, the optional plating seed layer has a thickness from 2 nm to 400 nm. The optional plating seed layer can be formed by a conventional deposition process including, for example, chemical vapor deposition (CVD), plasma-enhanced chemical vapor deposition (PECVD), atomic layer deposition (ALD), and physical vapor deposition (PVD) techniques that may include evaporation and/or sputtering.

In accordance with the present disclosure, the optional metal-containing adhesion layer 14 and/or the optional plating seed layer is (are) formed at a temperature which does not effectuate spontaneous spalling to occur within the base substrate 10. By “spontaneous” it is meant that the removal of a thin material layer from a base substrate occurs without the need to employ any manual means to initiate crack formation and propagation for breaking apart the thin material layer from the base substrate. By “manual” it is meant that crack formation and propagation are explicit for breaking apart the thin material layer from the base substrate.

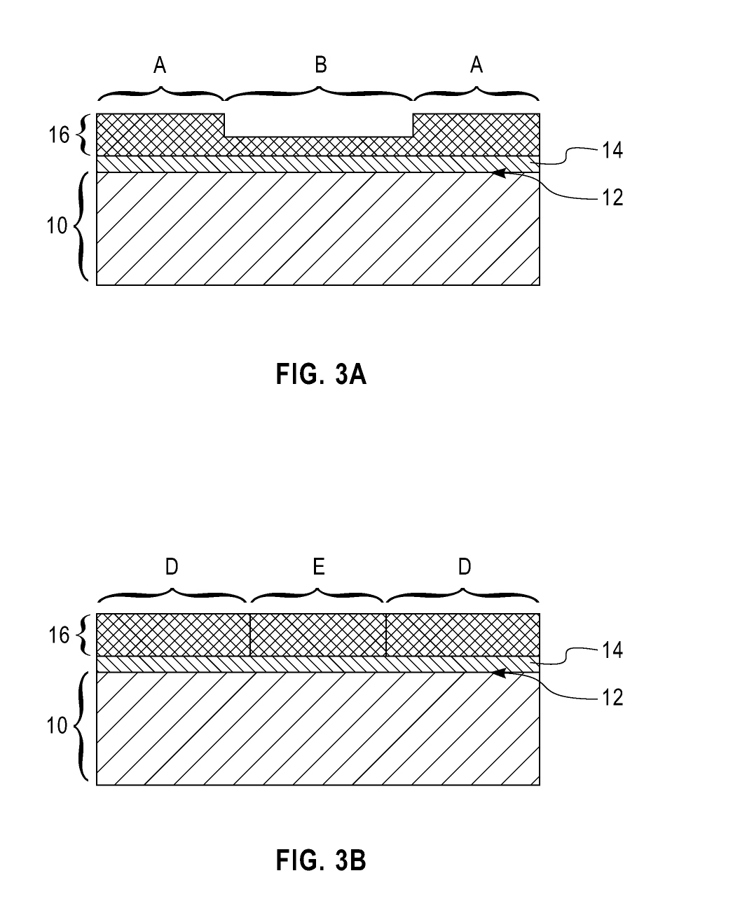

Referring now to FIGS. 3A and 3B, there are illustrated the structure of FIG. 2 after forming a differential-fracture-generating-stressor layer 16 atop the base substrate 10. In the particular embodiments illustrated in FIGS. 3A and 3B, the differential-fracture-generating-stressor layer 16 is formed directly on the uppermost surface of optional metal-containing adhesion layer 14. In other embodiments which are not illustrated in the drawings, the differential-fracture-generating-stressor layer 16 can be formed directly on the uppermost surface 12 of base substrate 10. In yet other embodiments which are not illustrated in the drawings, the differential-fracture-generating-stressor layer 16 can be formed directly on the uppermost surface of the optional plating seed layer.

In the embodiment depicted in FIG. 3A, the differential-fracture-generating-stressor layer 16 has a selected surface morphology having a modulation, i.e., non-uniformity, in thickness. In some embodiments, the differential-fracture-generating-stressor layer 16 has at least a first region A of a first thickness and at least a second region B of a second thickness, wherein the first thickness is different from the second thickness. During subsequent spalling, the difference in thickness of the differential-fracture-generating-stressor layer 16 induces fracturing within different depths and planes within the base substrate 10 which follows the modulation in thickness of the differential-fracture-generating-stressor layer 16.

In the embodiment depicted in FIG. 3B, the differential-fracture-generating-stressor layer 16 has at least one selected region having a modulation, i.e., non-uniformity, in at least one physical property such as for example, stress or Young's Modulus. Young's Modulus also known as the tensile modulus, is a measure of the stiffness of a material and is a quantity used to characterize materials. Young's Modulus is typically defined as the ratio of the unaxial stress over the uniaxial stain in the range of stress in which Hooke's Law holds. In some embodiments, and as shown in FIG. 3B, the differential-fracture-generating-stressor layer 16 has at least a first region D of a first physical property and at least a second region E of a second physical property, wherein the first physical property is different from the second physical property. The difference in physical properties of the differential-fracture-generating-stressor layer 16 induces fracturing within the base substrate 10 at different depths and fracture planes which follows the modulation in physical properties of the differential-fracture-generating-stressor layer 16.

Notwithstanding whether the differential-fracture-generating-stressor layer 16 has a difference in thickness or physical property, the differential-fracture-generating-stressor layer 16 employed in the present disclosure includes any material that is under tensile stress on base substrate 10 at the spalling temperature. As such, the stressor material can also be referred to herein as a stress-inducing material. In accordance with the present disclosure, the differential-fracture-generating-stressor layer 16 has a critical thickness and stress value that cause spalling mode fracture to occur within the base substrate 10. By “spalling mode fracture” it is meant that a crack is formed within base substrate 10 and the combination of loading forces maintain a crack trajectory at a depth below the stressor/substrate interface. By “critical condition”, it is meant that for a given stressor material and base substrate material combination, a thickness value and a stressor value for the stressor layer is chosen that render spalling mode fracture possible (can produce a K_{I} value greater than the K_{IC} of the substrate).

The thickness of the differential-fracture-generating-stressor layer 16 is chosen to provide a desired fracture depth(s) within the base substrate 10. For example, if the differential-fracture-generating-stressor layer 16 is chosen to be Ni, then fracture will occur at a depth below the stressor layer 16 roughly 2 to 3 times the Ni thickness. The stress value for the differential-fracture-generating-stressor layer 16 is chosen to satisfy the critical condition for spalling mode fracture. This can be estimated by inverting the empirical equation given by t*=[(2.5×10⁶)(K_{IC}^{3/2})]/σ², where t* is the critical stressor layer thickness (in microns), K_{IC} is the fracture toughness (in units of MPa·m^{1/2}) of the base substrate 10 and a is the stress value of the stressor layer (in MPa or megapascals). The above expression is a guide, in practice, spalling can occur at stress or thickness values up to 20% less than that predicted by the above expression.

Illustrative examples of materials that are under tensile stress when applied atop the base substrate 10 and thus can be used as the differential-fracture-generating-stressor layer 16 include, but are not limited to, a metal, a polymer, such as a spall inducing tape layer, or any combination thereof. The differential-fracture-generating-stressor layer 16 may comprise a single stressor material, or a multilayered stressor structure including at least two layers of different stressor material can be employed.

In one embodiment, the differential-fracture-generating-stressor layer 16 is a metal. In another embodiment, the differential-fracture-generating-stressor layer 16 is a spall inducing tape. In another embodiment, for example, the differential-fracture-generating-stressor layer 16 may comprise a two-part stressor layer including a lower part and an upper part. The upper part of the two-part stressor layer can be comprised of a spall inducing tape layer.

When a metal is employed as the differential-fracture-generating-stressor layer 16, the metal can include, for example, Ni, Cr, Fe, or W. Alloys of these metals can also be employed. In one embodiment, the differential-fracture-generating-stressor layer 16 includes at least one layer consisting of Ni.

When a polymer is employed as the differential-fracture-generating-stressor layer 16, the polymer is a large macromolecule composed of repeating structural units. These subunits are typically connected by covalent chemical bonds. Illustrative examples of polymers that can be employed as the differential-fracture-generating-stressor layer 16 include, but are not limited to, polyimides polyesters, polyolefins, polyacrylates, polyurethane, polyvinyl acetate, and polyvinyl chloride.

When a spall inducing tape layer is employed as the differential-fracture-generating-stressor layer 16, the spall inducing tape layer includes any pressure sensitive tape that is flexible, soft, and stress free at a first temperature used to form the tape, yet strong, ductile and tensile at a second temperature used during spalling. By “pressure sensitive tape,” it is meant an adhesive tape that will stick with application of pressure, without the need for solvent, heat, or water for activation. Tensile stress in the tape at the second temperature is primarily due to thermal expansion mismatch between the base substrate 10 (with a lower thermal coefficient of expansion) and the tape (with a higher thermal expansion coefficient).

Typically, the pressure sensitive tape that is employed in the present disclosure as differential-fracture-generating-stressor layer 16 includes at least an adhesive layer and a base layer. Materials for the adhesive layer and the base layer of the pressure sensitive tape include polymeric materials such as, for example, acrylics, polyesters, olefins, and vinyls, with or without suitable plasticizers. Plasticizers are additives that can increase the plasticity of the polymeric material to which they are added.

In the embodiment that is illustrated in FIG. 3A, the differential-fracture-generating-stressor layer 16 can be formed utilizing any desired combination of blanket deposition, patterned deposition, blanket etching, and patterned etching. Examples of patterned deposition include deposition through a shadow mask or lift-off stencil, as well as through-mask plating. Examples of patterned etching include wet etch and dry etch processes performed through a mask, as well as typically maskless processes such as laser ablation. Generally, deposition may be accomplished by any of dip coating, spin-coating, brush coating, sputtering, chemical vapor deposition, plasma enhanced chemical vapor deposition, chemical solution deposition, physical vapor deposition, and plating to form the differential-fracture-generating-stressor layer 16 that includes a metal or polymer as the stressor material.

In the embodiment illustrated in FIG. 3B, a blanket layer of stressor material can be applied and then a region of modulated physical property (i.e., stress or Young's Modulus) can be created within preselected portions of the stressor material formed by locally heating and/or melting the preselected portions of the stressor material. For example, local heating of the stressor material may result in a localized increase in stressor grain size, with a consequent change in the local stress. In one embodiment, laser annealing can be used. When laser annealing is used, the preselected portions of the stressor material are laser irradiated at fluencies low enough to avoid significant material removal. The laser irradiation may be implemented with a fixed-position laser beam directed to a sample on a moving stage, with a fixed-position sample and an adjustable-position laser beam, or any combination. A variety of wavelengths, pulse lengths (continuous to fs), focus conditions, repetition rates, scan rates, and fluences may be used. In one embodiment, pulsed irradiation is typically used because it allows a more localized heating. A typical laser anneal for a Ni film 5 μm to 30 μm in thickness might be performed with a wavelength of 1064 nm, pulses of duration 20 ns to 30 ns, repetition rates of 60 kHz, pulse energies of 50 μJ to 250 μJ, and a spot size of about 50 μm diameter, corresponding to a fluence of 3 J/cm² to 10 J/cm², with a scan rate of 100 mm/s.

Notwithstanding the technique employed in forming the differential-fracture-generating-stressor layer 16, the differential-fracture-generating-stressor layer 16 is at a first temperature which is at room temperature (15° C.-40° C.). In another embodiment, when a tape layer is employed, the tape layer can be formed at a first temperature which is from 15° C. to 60° C.

If the differential-fracture-generating-stressor layer 16 is of a metallic nature, it typically has a thickness within a range from 3 μm to 50 μm, with a thickness within a range from 4 μm to 7 μm being more typical. Other thicknesses for the differential-fracture-generating-stressor layer 16 that are below and/or above the aforementioned thickness ranges can also be employed in the present disclosure.

If the differential-fracture-generating-stressor layer 16 is of a polymeric nature, it typically has a thickness in a range from 10 μm to 200 μm, with a thickness within a range from 50 μm to 100 μm being more typical. Other thicknesses for the differential-fracture-generating-stressor layer 16 that are below and/or above the aforementioned thickness ranges can also be employed in the present disclosure.

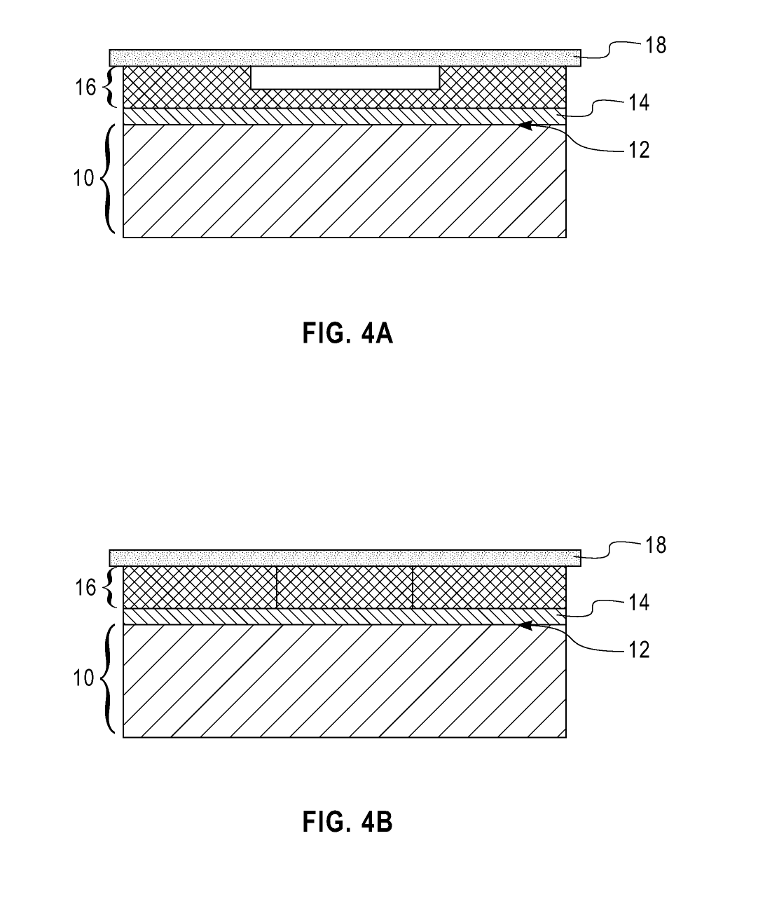

Referring to FIGS. 4A and 4B, there are depicted the structure of FIGS. 3A and 3B, respectively, after forming an optional handle substrate 18 atop differential-fracture-generating-stressor layer 16. The optional handle substrate 18 employed in the present disclosure comprises any flexible material which has a minimum radius of curvature that is typically less than 30 cm. Illustrative examples of flexible materials that can be employed as the optional handle substrate 18 include a metal foil or a polyimide foil. The optional handle substrate 18 can be used to provide better fracture control and more versatility in handling the spalled portion, i.e., the portion of the base substrate below the differential-fracture-generating-stressor layer 16 and above the fracture surfaces of the base substrate 10. Moreover, the optional handle substrate 18 can be used to guide the crack propagation during spalling. The optional handle substrate 18 of the present disclosure is typically, but not necessarily, formed at a first temperature which is at room temperature (15° C.-40° C.).

The optional handle substrate 18 can be formed utilizing deposition techniques that are well known to those skilled in the art including, for example, dip coating, spin-coating, brush coating, sputtering, chemical vapor deposition, plasma enhanced chemical vapor deposition, chemical solution deposition, physical vapor deposition, and plating. The optional handle substrate 18 typical has a thickness of from 1 μm to few mm, with a thickness of from 70 μm to 120 μm being more typical. Other thicknesses for the optional handle substrate 18 that are below and/or above the aforementioned thickness ranges can also be employed in the present disclosure.

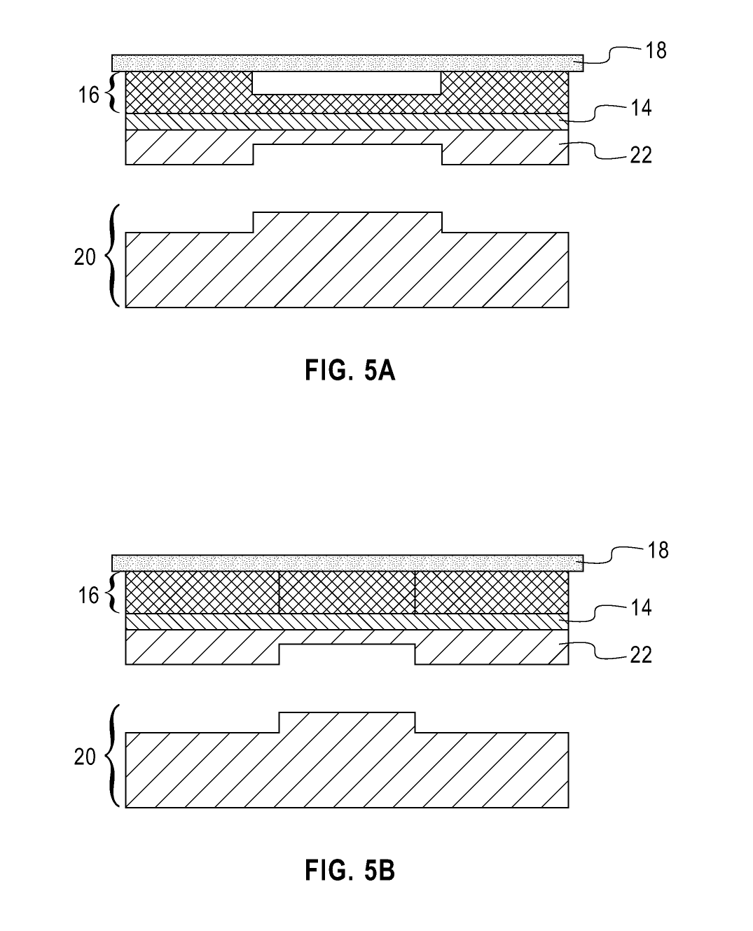

Referring now to FIGS. 5A-5B, there are depicted the structures of FIGS. 4A and 4B after removing a material layer 22 from the base substrate 10 by spalling. Material layer 22 can also be referred to herein as a spalled material layer portion of the base substrate 10. In the drawings, reference numeral 20 denotes a remaining portion, i.e., non-spalled portion, of the base substrate 10 that is not attached to the differential-fracture-generating-stressor layer.

Spalling can be initiated at room temperature or at a temperature that is less than room temperature. In one embodiment, spalling is performed at room temperature (i.e., 20° C. to 40° C.). In another embodiment, spalling is performed at a temperature less than 20° C. In a further embodiment, spalling occurs at a temperature of 77 K or less. In an even further embodiment, spalling occurs at a temperature of less than 206 K. In still yet another embodiment, spalling occurs at a temperature from 175 K to 130 K.

When a temperature that is less than room temperature is used, the less than room temperature spalling process can be achieved by cooling the structure down below room temperature utilizing any cooling means. For example, cooling can be achieved by placing the structure in a liquid nitrogen bath, a liquid helium bath, an ice bath, a dry ice bath, a supercritical fluid bath, or any cryogenic environment liquid or gas.

When spalling is performed at a temperature that is below room temperature, the spalled structure is returned to room temperature by allowing the spalled structure to slowly warm up to room temperature by allowing the same to stand at room temperature. Alternatively, the spalled structure can be heated up to room temperature utilizing any heating means.

After spalling, the optional handle substrate 18, differential-fracture-generating-stressor layer 16, and, if present the optional plating seed layer and the optional metal-containing adhesion layer 14 can be removed from the material layer 22 of the base substrate 10. The optional handle substrate 18, the differential-fracture-generating-stressor layer 16 and the optional plating seed layer and the optional metal-containing adhesion layer 14 can be removed from the material layer 22 of the base substrate utilizing conventional techniques well known to those skilled in the art. For example, and in one embodiment, aqua regia (HNO₃/HCl) can be used for removing the optional handle substrate 18, the differential-fracture-generating-stressor layer 16, the optional plating seed layer and the optional metal-containing adhesion layer 14. In another example, UV or heat treatment is used to remove the optional handle substrate 18, followed by a chemical etch to remove the differential-fracture-generating stressor layer 16, followed by a different chemical etch to remove the optional plating seed layer and optional metal-containing adhesion layer 14.

The thickness of the material layer 22 spalled from the base substrate 10 varies depending on the material of the differential-fracture-generating stressor layer 16 and the material of the base substrate 10 itself. In one embodiment, the material layer 22 spalled from the base substrate 10 has a thickness of less than 100 microns. In another embodiment, the material layer 22 spalled from the base substrate 10 has a thickness of less than 50 microns.

The material layer 22 and the remaining portion of the base substrate 20 that are providing after spalling each have a surface morphology following the modulation in thickness or the at least one physical property of the differential-fracture-generating-stressor layer 16. Specifically, the material layer 22 and the remaining portion of the base substrate 20 have complementary surface morphologies that follow the modulation in thickness or the at least one physical property of the differential-fracture-generating-stressor layer 16.

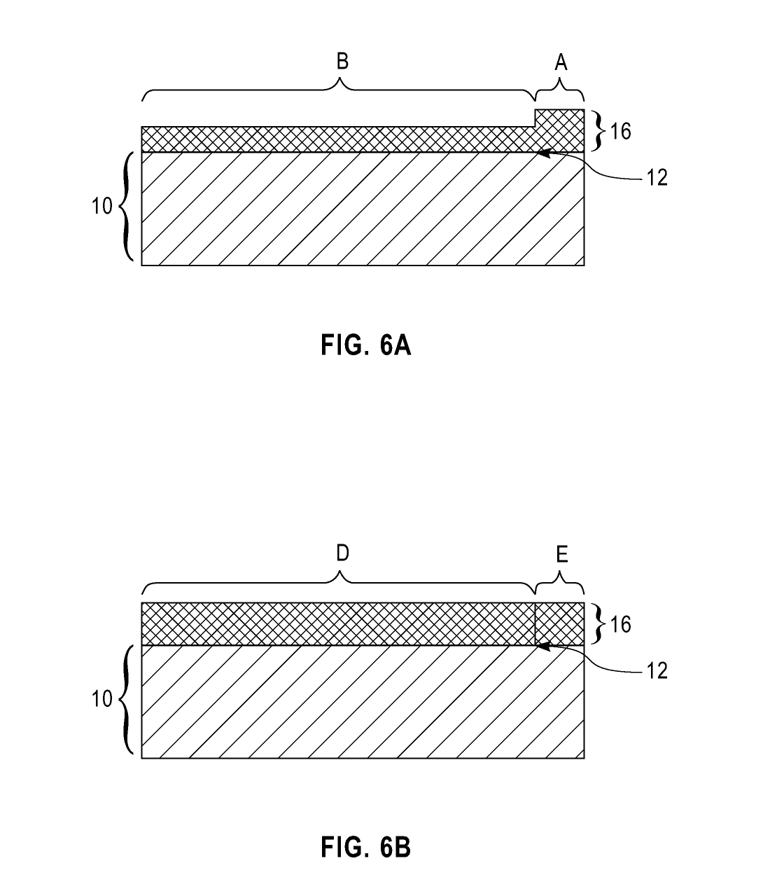

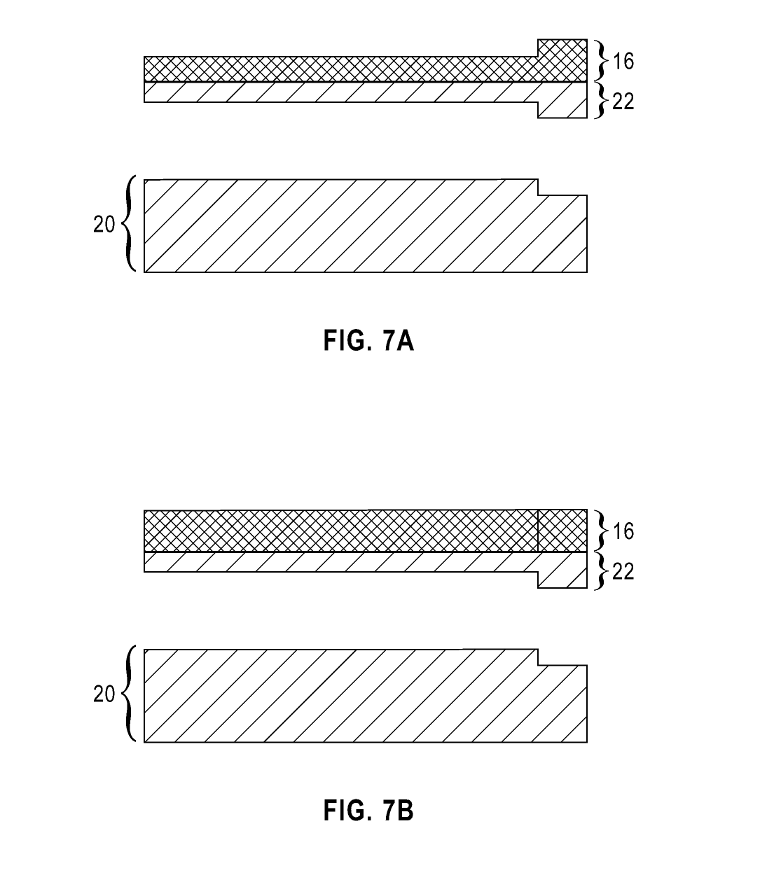

Reference is now made to FIGS. 6A, 6B, 7A, and 7B which illustrate other embodiments of the present disclosure for generating surface patterns. In these embodiments, the surface pattern is generated near an edge of the base substrate. Referring first to FIG. 6A, there is illustrated a structure after forming a differential-fracture-generating-stressor layer 16 having a non-uniformity in thickness atop a base substrate 10, the non-uniformity in thickness of the differential-fracture-generating-stressor layer 16 is located near one edge of the base substrate 10. In this drawing, the length of region A is a few microns or less from the edge of base substrate 10. Although not shown, optional plating seed layer and/or an optional metal-containing adhesion layer 14 can be formed beneath the differential-fracture-generating-stressor layer 16. Also, a handle substrate 18 can be formed atop the differential-fracture-generating-stressor layer 16.

FIG. 6B illustrates a structure after forming a differential-fracture-generating-stressor layer 16 having a non-uniformity in at least one physical property located atop a base substrate 10, the non-uniformity in the at least one physical property of the differential-fracture-generating-stressor layer 16 is located near one edge of the base substrate 10. In this drawing, the length of region E is a few microns or less from the edge of base substrate 10. Although not shown, optional plating seed layer and/or an optional metal-containing adhesion layer 14 can be formed beneath the differential-fracture-generating-stressor layer 16. Also, a handle substrate 18 can be formed atop the differential-fracture-generating-stressor layer 16.

Referring to FIGS. 7A-7B, there are depicted the structures of FIG. 6A and FIG. 6B after spalling is performed utilizing the conditions described herein above. The material layer 22 and the remaining portion of the base substrate 20 that are providing after spalling each have a surface morphology following the modulation in thickness or the at least one physical property of the differential-fracture-generating-stressor layer 16. Specifically, the material layer 22 and the remaining portion of the base substrate 20 have complementary surface morphologies that follow the modulation in thickness or the at least one physical property of the differential-fracture-generating-stressor layer 16. In this embodiment, the surface pattern is located near an edge of material layer 22 and the remaining portion of the base substrate 20.

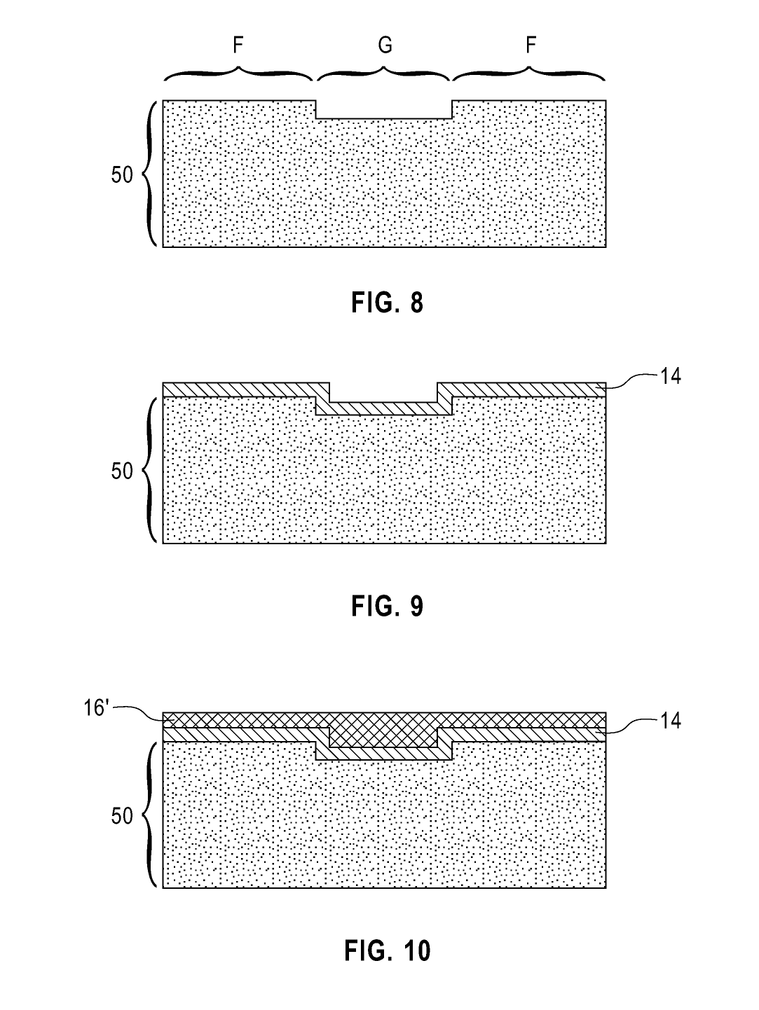

In another aspect of the present disclosure, spalling is used to replicate surface patterns. This aspect of the present disclosure will now be described in greater detail by referring to FIGS. 8-18. This aspect of the present disclosure includes providing a base substrate having a selected surface morphology. A stressor layer is formed atop the base substrate including the selected surface morphology. A material layer is then spalled from the base substrate. After spalling, the material layer from the base substrate has a spalled surface that at least partially replicates the selected surface morphology, and a remaining portion of the base substrate has a surface with a morphology complementary to the at least partially replicated surface morphology.

Referring first to FIG. 8, there is shown a base substrate 50 having a non-uniform uppermost surface that can be employed in another embodiment of the present disclosure. Base substrate 50 can be comprised of one of the materials mentioned above for base substrate 10. In this embodiment, base substrate 50 is patterned, while in the previous embodiments base substrate 10 was non-patterned. Patterning can be achieved by conventional techniques well known in the art including, for example, photolithography and etching. Regions F and G represent different portions of the base substrate 50 whose thickness is different. In the particular embodiment illustrated, regions F have a thickness that is greater than region G. The surface morphology provided by this non-uniformity in thickness of the base substrate can be replicated by spalling.

Referring now to FIG. 9, there is illustrated the structure of FIG. 9 after forming an optional metal-containing adhesion layer 14 on the uppermost surface of the base substrate 50. The optional metal-containing adhesion layer 14 can be comprised of one of the materials mentioned above and it can be formed utilizing one of the techniques mentioned above as well. Although not shown, an optional plating seed layer can be formed as described above as well.

Referring now to FIG. 10, there is depicted the structure of FIG. 9 after forming a stressor layer 16′ on a surface of the optional metal-containing adhesion layer 14. The stressor layer 16′ employed in this embodiment of the present disclosure includes one of the stressor materials as mentioned above for differential-fracture-generating-stressor layer 16. Stressor layer 16′ can be formed by utilizing one of the deposition methods described above in forming the stressor material for differential-fracture-generating-stressor layer 16. Alternative, the stressor layer 16′ can be formed on the structure by hand or by mechanical means.

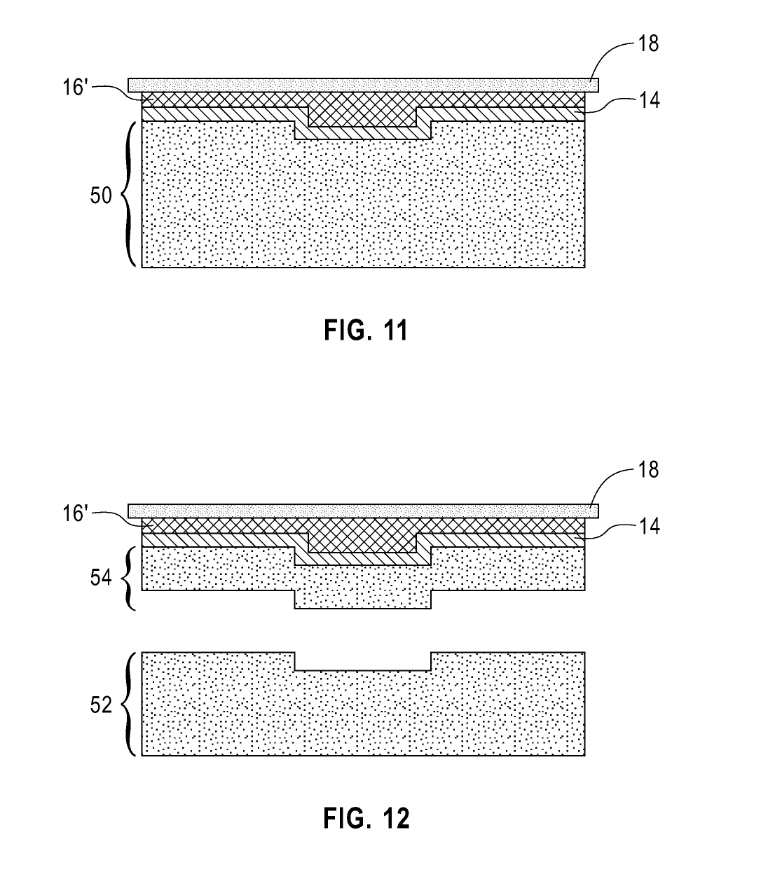

Referring now to FIG. 11, there is shown the structure of FIG. 10 after forming an optional handle substrate 18 atop the stressor layer 16′. The optional handle substrate 18 is comprised of one of the materials described above and it is formed utilizing one of the methods mentioned above as well.

Referring now to FIG. 12, there is illustrated the structure of FIG. 11 after spalling utilizing the spalling conditions, i.e., temperatures, as mentioned above. In this embodiment, the spalled material layer 54 from the base substrate has a spalled surface that at least partially replicates the selected surface morphology of the original base substrate 50, and a remaining portion of the base substrate 52 has a surface with a morphology complementary to the at least partially replicated surface morphology.

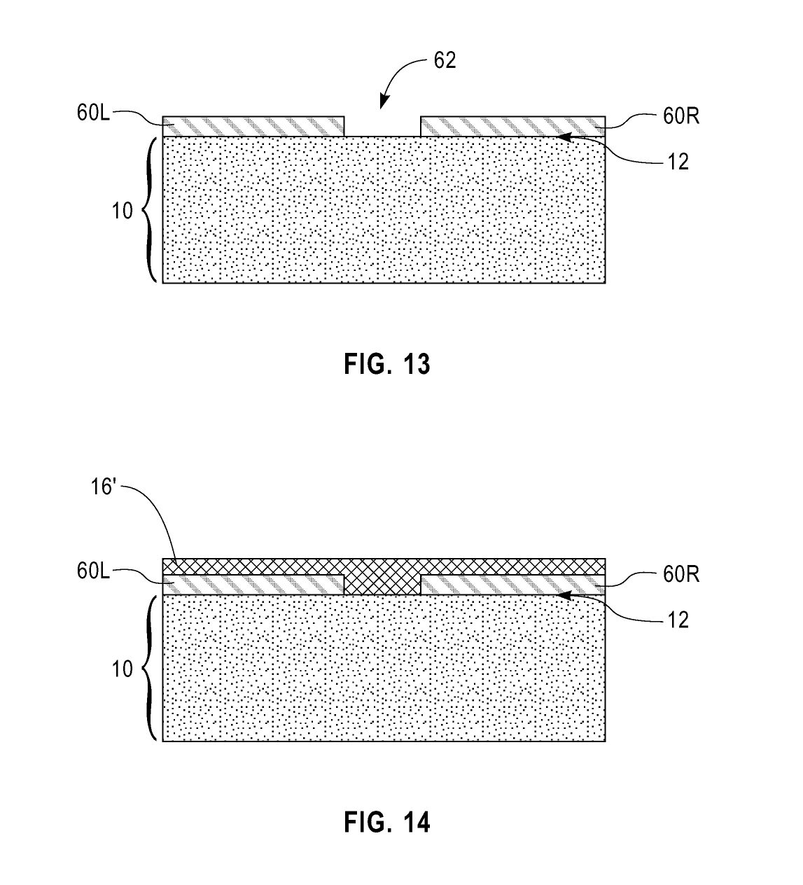

Referring now to FIG. 13, there is illustrated the base substrate 10 of FIG. 1 after forming a mask 60L, 60R having at least one opening 62 atop the base substrate 10. The mask 60L, 60R having the at least one opening 62 provides a selected surface morphology atop the base substrate 10. The mask 60L, 60R is formed by first providing a blanket layer mask material atop the base substrate 10 utilizing a conventional deposition technique. The mask material can comprise an inorganic mask material such as, for example, an oxide, a nitride, an oxynitride, or any combination thereof. Alternatively, the mask material can comprise an antireflective coating, a photoresist or any combination thereon. In some embodiments, the mask material can include a multilayered stack of inorganic and/or organic mask materials. Lithography and optional etching can be used to pattern the blanket layer of mask material.

Referring now to FIG. 14, there is depicted the structure of FIG. 13 after forming a stressor layer 16′ atop the mask 60L, 60R. The stressor layer 16′ includes one of the stressor materials mentioned above for differential-fracture-generating-stressor layer 16. Although not shown, an optional handle substrate as defined above can be formed atop the stressor layer 16′ at this point of the present disclosure.

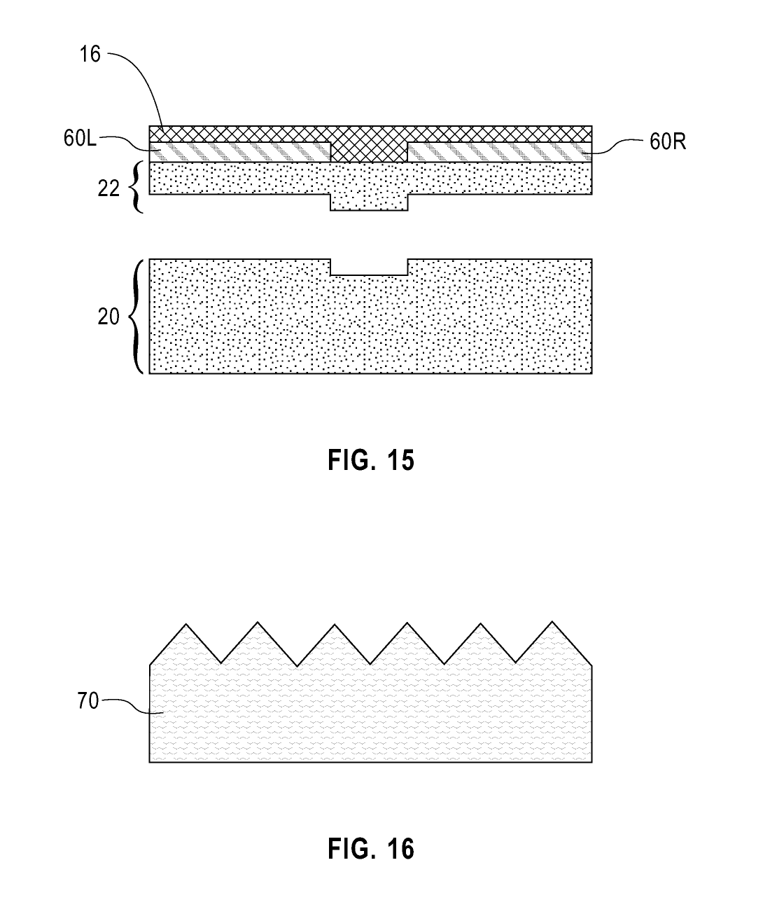

Referring now to FIG. 15, there is depicted the structure of FIG. 14 after spalling utilizing the spalling conditions, i.e., temperatures, mentioned above. In this embodiment, the spalled material layer 22 from the base substrate has a spalled surface that at least partially replicates the selected surface morphology of the structure that is provided by mask 601, 60R atop the base substrate 10, and a remaining portion of the base substrate 20 has a surface with a morphology complementary to the at least partially replicated surface morphology.

Referring now to FIG. 16, there is depicted a base substrate 70 having a non-uniform uppermost surface that can be employed in another embodiment of the present disclosure. Base substrate 70 may be comprised of one of the materials mentioned above for base substrate 10. In one embodiment, base substrate 70 is comprised of a semiconductor material such as silicon and is a component of a solar cell. In one embodiment, the base substrate 10 has a selected surface morphology that is in the form of non-inverted pyramids.

The base substrate 70 can be prepared by first providing base substrate 10 and then texturing the uppermost surface 12 of the base substrate 10 within any of the well known texturing methods.

In one embodiment, non-inverted pyramids are formed by utilizing a KOH based solution, a HNO₃/HF solution, or by utilizing a combination of reactive ion etching (RIE) and a mask comprising closely packed self-assembled polymer spheres. Other selected surface morphologies besides non-inverted pyramids can also be utilized for base substrate 70.

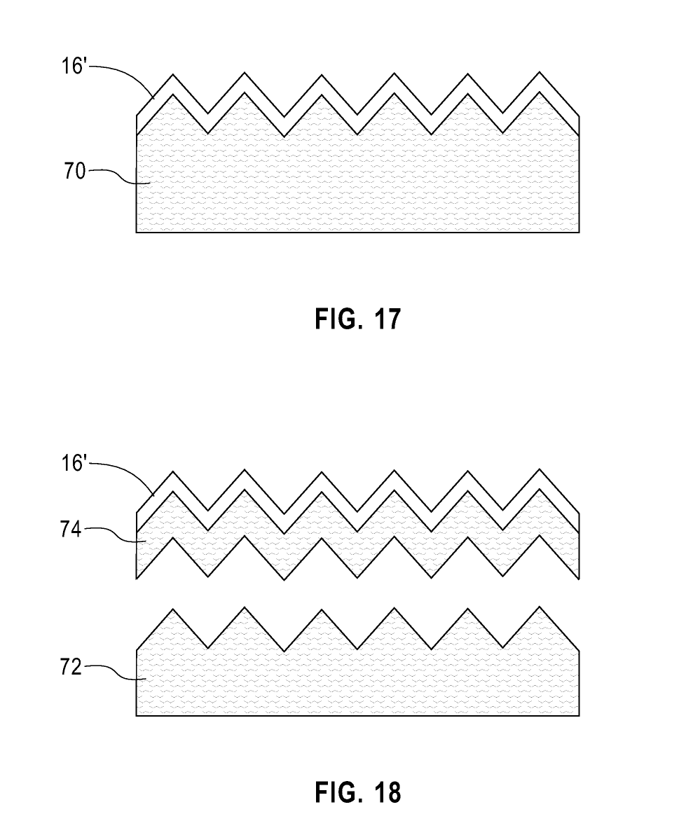

Referring now to FIG. 17, there is illustrated the structure of FIG. 16 after forming a stressor layer 16′ atop the base substrate 70. In some embodiments, stressor layer 16′ is non-planar and has a shape that follows the selected surface morphology of the base substrate 70. In yet other embodiments, a planar stressor layer 16′ as depicted, for example, in FIG. 14 can be employed. The stressor layer 16′ includes one of the stressor materials mentioned above for differential-fracture-generating-stressor layer 16.

Referring to FIG. 18, there is illustrated the structure of FIG. 17 after spalling utilizing the spalling conditions, i.e., temperature, as mentioned above. In this embodiment, the spalled material layer 74 from the base substrate has a spalled surface that at least partially replicates the selected surface morphology of original base substrate 70, and a remaining portion of the base substrate 72 has a surface with a morphology complementary to the at least partially replicated surface morphology.

It is noted that for the replication of the surface patterns, the replicated surface pattern that is formed on the spalled material is located on a surface that is opposing the original uppermost surface of the base substrate. It is also noted the optional handle substrate, stressor material, optional metal-containing adhesion layer and optional plating seed layer can be removed from any of the embodiments of the present disclosure using one of the techniques described above.

While the present disclosure has been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed as new is:

1. A method of generating surface patterns comprising:
forming a differential-fracture-generating-stressor layer atop a base substrate, said differential-fracture-generating-stressor layer having a modulation in thickness or at least one physical property; and
spalling a material layer from the base substrate, wherein said material layer from the base substrate and a remaining portion of the base substrate have complementary surface morphologies that follow the modulation in thickness or the at least one physical property of said differential-fracture-generating-stressor layer.

2. The method of claim 1, further comprising forming a metal-containing adhesion layer beneath said differential-fracture-generating-stressor layer.

3. The method of claim 1, further comprising forming a handle substrate atop said differential-fracture-generating-stressor layer.

4. The method of claim 1, wherein said differential-fracture-generating-stressor layer has a modulation in thickness.

5. The method of claim 4, wherein said differential-fracture-generating-stressor layer has at least a first region of a first thickness and at least a second region of a second thickness, wherein said first thickness is different from said second thickness.

6. The method of claim 4, wherein said differential-fracture-generating-stressor layer is formed by through-mask deposition or a lift-off method.

7. The method of claim 1, wherein said differential-fracture-generating-stressor layer has a modulation of said at least one physical property.

8. The method of claim 1, wherein said at least one physical property is selected from the group consisting of stress and Young's Modulus.

9. The method of claim 7, wherein said differential-fracture-generating-stressor layer has at least a first region of a first physical property and at least a second region of a second physical property, wherein said first physical property is different from said second physical property.

10. The method of claim 7, wherein said differential-fracture-generating-stressor layer is formed by laser annealing at least one region of a blanket stressor layer.

11. The method of claim 1, wherein said differential-fracture-generating-stressor layer comprises a metal, a polymer or any combination thereof.

12. The method of claim 11, wherein said differential-fracture-generating-stressor layer comprises at least said polymer, and said polymer comprises a spall inducing tape layer.

13. The method of claim 1, wherein said spalling is performed at room temperature or at a temperature below room temperature.

14. The method of claim 1, wherein said modulation in thickness or at least one physical property is located near an edge of said base substrate.

15. A method of replicating surface patterns comprising:
providing a base substrate having a selected surface morphology;
forming a stressor layer atop the base substrate including said selected surface morphology; and
spalling a material layer from the base substrate, wherein said material layer from the base substrate has a spalled surface that at least partially replicates said selected surface morphology, and wherein a remaining portion of the base substrate has a surface with a morphology complementary to the at least partially replicated surface morphology.

16. The method of claim 15, further comprising forming a metal-containing adhesion layer beneath said stressor layer.

17. The method of claim 15, further comprising forming a handle substrate atop said stressor layer.

18. The method of claim 15, wherein said stressor layer comprises a metal, a polymer or any combination thereof.

19. The method of claim 18, wherein said stressor layer comprises at least said polymer, and said polymer comprises a spall inducing tape layer.

20. The method of claim 15, wherein said spalling is performed at room temperature or at a temperature below room temperature.

21. The method of claim 15, wherein said selected surface morphology is located within an uppermost surface of said base substrate.

22. The method of claim 15, wherein said selected surface morphology is provided by a mask located on an uppermost surface of said base substrate.

23. The method of claim 15, wherein said selected surface morphology is non-inverted pyramids located within an uppermost surface of said base substrate, and said base substrate comprises a semiconductor material.

24. The method of claim 23, wherein said non-inverted pyramids are formed by utilizing a KOH based solution, a HNO₃/HF solution, or by utilizing a combination of reactive ion etching (RIE) and a mask comprising closely packed self-assembled polymer spheres.

25. The method of claim 23, wherein said stressor layer is non-planar and has a shape that follows the selected surface morphology of said base substrate.
